(19) United States
(12) Patent Application Publication
(10) Pub. No.: US 2025/0031448 A1
(43) Pub. Date: Jan. 23, 2025

(54) Backside Contact With Self-Aligned Gate Isolation

(71) Applicant: INTERNATIONAL BUSINESS MACHINES CORPORATION, ARMONK, NY (US)

(72) Inventors: Tao Li, Slingerlands, NY (US); Ruilong Xie, Niskayuna, NY (US); Nicholas Alexander Polomoff, Hopewell Junction, NY (US); Joshua M. Rubin, Albany, NY (US)

(21) Appl. No.: 18/357,085

(22) Filed: Jul. 21, 2023

(51) Int. Cl. H01L 27/12

(52) U.S. Cl. CPC H01L 27/124; H01L 27/1266

(57) ABSTRACT

A semiconductor device includes source and drain regions above a substrate layer and a dielectric bar between each of the source and drain regions. Each of the source and drain regions has a filleted shape, with a bottom portion of the filleted shape including a horizontal bottom surface connecting two sloped surfaces. Two sloped surfaces on a backside of the semiconductor device are surrounded by a metal contact.

### BACKGROUND

### Technical Field

The present disclosure generally relates to transistors and, more particularly, to nanosheet transistors with self-aligned gate isolation and methods of creation thereof.

### Description of the Related Art

Backside contacts provide a way to establish electrical connections with the backside or substrate of a transistor and enable efficient signal transmission, improved device performance, and enhanced manufacturing processes. In a typical transistor structure, the backside or substrate region is distinct from the active region where the transistor's channel and source/drain regions are located. The electrical connection established by the backside contacts provides a pathway for electrical signals, current, and voltage to flow, allowing communication between different components of an integrated circuit.

### SUMMARY

According to an embodiment, a semiconductor device includes one or more source and drain regions above a substrate layer and a first dielectric bar between each of the one or more source and drain regions. Each of the one or more source and drain regions can have a filleted shape. A bottom portion of the filleted shape can include a horizontal bottom surface connecting two sloped surfaces. Two sloped surfaces on a backside of the semiconductor device are surrounded by a metal contact.

In one embodiment, the semiconductor device can include a plurality of nanosheet gates extended between the one or more source and drain regions and a second dielectric bar between each two nanosheet gates of the plurality of nanosheet gates.

In some embodiments, which can be combined with the previous embodiment, the semiconductor device can further include an airgap between two sloped surfaces on a frontside of the semiconductor device. The airgap can be sealed by the first dielectric bar, a shallow trench isolation layer and a gate.

In additional embodiments, which can be combined with one or more previous embodiments, the semiconductor device includes a placeholder located under at least one of the one or more source and drain regions. The placeholder can be in contact with the horizontal bottom surface. In several embodiments, the placeholder is not in contact with two sloped surfaces on a frontside of the semiconductor device.

In an embodiment, which can be combined with one or more previous embodiments, a first critical dimension of the metal contact can be larger than a second critical dimension of the placeholder. The first and second critical dimensions are extended in a first direction. Additionally, or in the alternative, a third critical dimension of the metal contact can be substantially equal to a fourth critical dimension of the placeholder. The third and fourth critical dimensions are extended in a second direction.

In some embodiments, which can be combined with one or more previous embodiments, the metal contact is in contact with the first dielectric bar.

In an embodiment, which can be combined with one or more previous embodiments, the semiconductor device can further include a backside interlayer dielectric (BILD) located under a shallow trench isolation (STI). The BILD can include materials different than the STI, a self-aligned substrate isolation layer, and a gate isolation layer. The gate isolation layer can include nitride. Further, the BILD can include SiC or SiOC.

According to another embodiment, which can be combined with one or more previous embodiments, a method for forming a semiconductor device is disclosed. The method can include forming one or more source and drain regions above a substrate layer. Each of the one or more source and drain regions can have a filleted shape. A bottom portion of the filleted shape can include a horizontal bottom surface connecting two sloped surfaces. The method can include forming a first dielectric bar between each of the one or more source and drain regions and forming a metal contact surrounding two sloped surfaces on a backside of the semiconductor device.

In an embodiment, which can be combined with one or more previous embodiments, the method can include forming a plurality of nanosheet gates extended between the one or more source and drain regions and forming a second dielectric bar between each two nanosheet gates of the plurality of nanosheet gates.

In some embodiments, which can be combined with one or more previous embodiments, the method can include forming an airgap between two sloped surfaces on a frontside of the semiconductor device. Forming the airgap can include sealing the airgap with the first dielectric bar and a shallow trench isolation layer.

In several embodiments, which can be combined with one or more previous embodiments, the method can include forming a placeholder located under at least one of the one or more source and drain regions.

In an embodiment, which can be combined with one or more previous embodiments, the method can include forming a backside interlayer dielectric (BILD) located under a shallow trench isolation (STI).

According to some embodiments, which can be combined with one or more previous embodiments, a semiconductor device is disclosed. The semiconductor device can include one or more source and drain regions above a substrate layer, an airgap between two sloped surfaces on a frontside of the semiconductor device, and a first dielectric bar between each of the one or more source and drain regions. Each of the one or more source and drain regions can have a filleted shape. A bottom portion of the filleted shape includes a horizontal bottom surface connecting two sloped surfaces.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1C illustrate a semiconductor device, in accordance with some embodiments.

FIG. 1D depicts the top-view sections from which the semiconductor device is illustrated.

FIGS. 2A-2C illustrate side-views of a semiconductor device after the formation of the alternating layers of Si and SiGe over a substrate, in accordance with some embodiments.

FIGS. 3A-3C illustrate side-views of a semiconductor device after the patterning of a first active layer, in accordance with some embodiments.

FIGS. 4A-4C illustrate side-views of a semiconductor device after the patterning of a second active layer, in accordance with some embodiments.

FIGS. 5A-5C illustrate side-views of a semiconductor device after the formation of a self-aligned substrate isolation, in accordance with some embodiments.

FIGS. 6A-6C illustrate side-views of a semiconductor device after the formation of a sidewall spacer, in accordance with some embodiments.

FIGS. 7A-7C illustrate side-views of a semiconductor device after the formation of the dielectric bars, in accordance with some embodiments.

FIGS. 8A-8C illustrate side-views of a semiconductor device after the gate is patterned, in accordance with some embodiments.

FIGS. 9A-9C illustrate side-views of a semiconductor device after nanosheets are recessed, and the inner spacer is formed, in accordance with some embodiments.

FIGS. 10A-10C illustrate side-views of a semiconductor device after growing the source and drain regions, in accordance with some embodiments.

FIGS. 11A-11C illustrate side-views of a semiconductor device after the growing of a placeholder, in accordance with some embodiments.

FIGS. 12A-12C illustrate side-views of a semiconductor device after the wafer bonding, in accordance with some embodiments.

FIGS. 13A-13C illustrate side-views of a semiconductor device after the removal of the substrate, in accordance with some embodiments.

FIGS. 14A-14C illustrate side-views of a semiconductor device after the removal of the etch stop layer and the remaining substrate, in accordance with some embodiments.

FIGS. 15A-15C illustrate side-views of a semiconductor device after the deposition of the backside ILD, in accordance with some embodiments.

FIGS. 16A-16C illustrate side-views of a semiconductor device after the patterning of the backside contact, in accordance with some embodiments.

FIGS. 17A-17C illustrate side-views of a semiconductor device after the removal of the sacrificial placeholder, in accordance with some embodiments.

FIGS. 18A-18C illustrate side-views of a semiconductor device after the etching of the shallow trench isolation, in accordance with some embodiments.

FIGS. 19A-19C illustrate side-views of a semiconductor device after the metallization of the backside contact, in accordance with some embodiments.

FIGS. 20A-20C illustrate side-views of a semiconductor device after the formation of the backside interconnect, in accordance with some embodiments.

FIGS. 21A-21B illustrate block diagrams of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

In some embodiments, a semiconductor device is disclosed. The semiconductor device can include one or more source and drain regions above a substrate layer, each of the one or more source and drain regions having a filleted shape. A bottom portion of the filleted shape includes a horizontal bottom surface connecting two sloped surfaces. The semiconductor device can include a first dielectric bar between each of the one or more source and drain regions. Two sloped surfaces on a backside of the semiconductor device are surrounded by a metal contact.

The semiconductor device of can further include a plurality of nanosheet gates extended between the one or more source and drain regions, and a second dielectric bar between each of two nanosheet gates of the plurality of nanosheet gates.

The semiconductor device can include an airgap between two sloped surfaces on a frontside of the semiconductor device. The airgap is sealed by the first dielectric bar, a shallow trench isolation layer and a gate.

The semiconductor device can further include a placeholder located under at least one of the one or more source and drain regions. The placeholder is in contact with the horizontal bottom surface, and the placeholder is not in contact with two sloped surfaces on a frontside of the semiconductor device. A first critical dimension of the metal contact is larger than a second critical dimension of the placeholder, and the first and second critical dimensions are extended in a first direction. Further, a third critical dimension of the metal contact is substantially equal to a fourth critical dimension of the placeholder, and the third and fourth critical dimensions are extended in a second direction.

In some embodiments, the metal contact is in contact with the first dielectric bar.

The semiconductor device includes a backside interlayer dielectric (BILD) located under a shallow trench isolation (STI). The BILD includes materials different than the STI, a self-aligned substrate isolation (SASI) layer, and a gate isolation layer. The gate isolation layer can be nitride. The BILD can be SiC or SiOC.

In some embodiments, a method for forming a semiconductor device is disclosed. The method can include forming one or more source and drain regions above a substrate layer, each of the one or more source and drain regions having a filleted shape. A bottom portion of the filleted shape includes a horizontal bottom surface connecting two sloped surfaces. The method can include forming a first dielectric bar between each of the one or more source and drain regions, and forming a metal contact surrounding two sloped surfaces on a backside of the semiconductor device.

In some embodiments, the method can further include forming a plurality of nanosheet gates extended between the one or more source and drain regions, and forming a second dielectric bar between each two nanosheet gates of the plurality of nanosheet gates.

The method can further include forming an airgap between two sloped surfaces on a frontside of the semiconductor device. Forming the airgap can include sealing the airgap with the first dielectric bar and a shallow trench isolation layer.

In some embodiments, the method can include forming a placeholder located under at least one of the one or more source and drain regions. The placeholder is in contact with the horizontal bottom surface, and the placeholder is not in contact with two sloped surfaces on a frontside of the semiconductor device. In some embodiments, a first critical dimension of the metal contact is larger than a second critical dimension of the placeholder. The first and second critical dimensions are extended in a first direction. A third critical dimension of the metal contact is substantially equal to a fourth critical dimension of the placeholder. The third and fourth critical dimensions are extended in a second direction.

In some embodiments, the method includes forming a backside interlayer dielectric (BILD) located under a shallow trench isolation (STI). The BILD includes materials different than the STI, a self-aliened substrate isolation layer, and a gate isolation layer.

In an embodiment, a semiconductor device is disclosed. The semiconductor device can include one or more source and drain regions above a substrate layer, each of the one or more source and drain regions having a filleted shape. A bottom portion of the filleted shape includes a horizontal bottom surface connecting two sloped surfaces. The semiconductor can include an airgap between two sloped surfaces on a frontside of the semiconductor device, and a first dielectric bar between each of the one or more source and drain regions.

The concepts herein relate to nanosheet transistors, which are fundamental electronic devices that have revolutionized the field of electronics, and gate isolation layers. Nanosheet transistors serve as building blocks for numerous electronic circuits and are widely used in various applications. Gate isolation refers to the technique employed in semiconductor device fabrication to electrically separate adjacent transistors or components within an integrated circuit (IC). Gate isolation involves creating insulating regions or structures between the gates of neighboring transistors to prevent electrical interference or leakage between such neighboring transistors. Thus, proper gate isolation is crucial for maintaining the desired electrical characteristics and functionality of individual transistors within the IC.

One function of gate isolation is to isolate individual transistors or components within an integrated circuit electrically. By preventing electrical interaction between adjacent gates, the gate isolation ensures that each transistor operates independently, preserving the desired electrical characteristics and preventing signal interference.

As semiconductor devices continue to shrink in size with advancements in technology, gate isolation becomes increasingly challenging. Shrinking device dimensions make it more difficult to achieve effective isolation between adjacent transistors, leading to potential leakage current issues and reduced device reliability.

An issue with the fabrication of transistors is work function metallization (WFM) patterning undercut. WFM is the process of depositing metal layers with specific work function values onto semiconductor devices or integrated circuits. The work function of a metal refers to the energy required to remove an electron from the metal's surface into the vacuum. By selecting metals with appropriate work functions, WFM aims to achieve desirable electrical characteristics and performance in semiconductor devices.

To tackle the above-mentioned problems, disclosed is a semiconductor device with a self-aligned gate isolation to prevent WFM patterning undercut. The semiconductor device includes source and drain regions above a substrate layer and a dielectric bar between each of the source and drain regions. Each of the source and drain regions has a filleted shape. In some embodiments, the filleted shape is an octagonal shape, a diamond shape, a hexagonal shape, or any other similar shape. In various embodiments, the filleted shape includes a bottom portion of the octagonal shape, including a horizontal bottom surface connecting two sloped surfaces. Two sloped surfaces on a backside of the semiconductor device are surrounded by a metal contact. The disclosed semiconductor device offers improved backside contact by utilizing self-aligned gate isolation.

The semiconductor device of the present disclosure uses gate isolation to help minimize leakage current between neighboring transistors. Leakage current can occur when there is an unintended electrical connection or path between transistors, leading to power consumption, reduced signal integrity, and potential device malfunctions. As such, the effective gate isolation technique disclosed herein can significantly reduce leakage and enhance the overall performance and efficiency of the IC. Additionally, noise interference can degrade signal quality and impact the performance of semiconductor devices. By isolating the gates of neighboring transistors, the present disclosure can help reduce noise propagation between the transistors. Disclosed gate isolation can further aid in minimizing noise coupling, ensuring reliable signal transmission, and maintaining the integrity of the desired electrical signals.

To that end, self-aligned gate isolation in a semiconductor device is disclosed. The disclosed self-aligned gate isolation can achieve precise and controlled isolation between adjacent transistors. The isolation regions can be formed using the gate structure itself as a mask during the fabrication process. The gate structure can be designed to self-align with the isolation regions, resulting in improved accuracy and reduced device size. Self-aligned gate isolation can further enable higher packing density, reduced parasitic capacitance, and enhanced device performance.

Disclosed is a semiconductor device that can further avoid WFM patterning undercut. WFM patterning undercut refers to a phenomenon that can occur during the patterning process of metal layers with different work functions on a semiconductor device or integrated circuit. The WFM patterning undercut involves the unintentional etching or removal of the underlying layers or materials, leading to a recessed or undercut profile of the patterned metal features.

The undercut typically occurs when the etching or patterning process, used to define the metal features selectively, removes the underlying materials, such as dielectric or semiconductor layers, along with the desired metal layer. Such an undercut can result in a void or recessed region beneath the metal, causing the metal feature to have a raised or overhanging appearance. The work function metallization patterning undercut can have various consequences on device performance and reliability. For example, the undercut can lead to unintended electrical shorts between adjacent metal features or between the metal and underlying layers, potentially causing malfunctions or failure of the device. The undercut can also reduce the effective contact area between the metal and the underlying layers, resulting in increased contact resistance and compromised electrical performance. Additionally, the recessed or raised metal features due to the undercut can introduce additional parasitic capacitance, negatively impacting circuit performance, especially in high-frequency applications. Last but not least, the undercut can weaken the structural integrity of the metal features, making them more susceptible to mechanical stress, delamination, or failure.

To mitigate or prevent work function metallization patterning undercut, the present disclosure employs several strategies. For instance, the etching process can be optimized by careful selection and optimization of the etching parameters, such as etchant composition, temperature, and duration. Additionally, by choosing suitable dielectric or passivation layers beneath the metal, the undercut can be prevented or reduced. Such dielectric or passivation layers should have good etch selectivity. That is, they are less susceptible to etching while the metal is being patterned. Further, by implementing sidewall passivation techniques, such as using conformal coatings or protective layers, the sidewalls of the metal features during the etching process can be protected. The disclosed semiconductor device can closely monitor and control the etching process parameters, such as etch rate, endpoint detection, and uniformity, to aid in minimizing the risk of undercut and ensuring consistent and reliable patterning.

By employing the above-mentioned measures, the present disclosure can provide mitigated work function metallization patterning undercut, which leads to improved device performance, enhanced reliability, and better control over the electrical properties of the metal-semiconductor interfaces.

Accordingly, the teachings herein provide methods and systems of semiconductor device formation with self-aligned gate isolation. The techniques described herein may be implemented in a number of ways. Example implementations are provided below with reference to the following figures.

### Example Semiconductor Device Structure

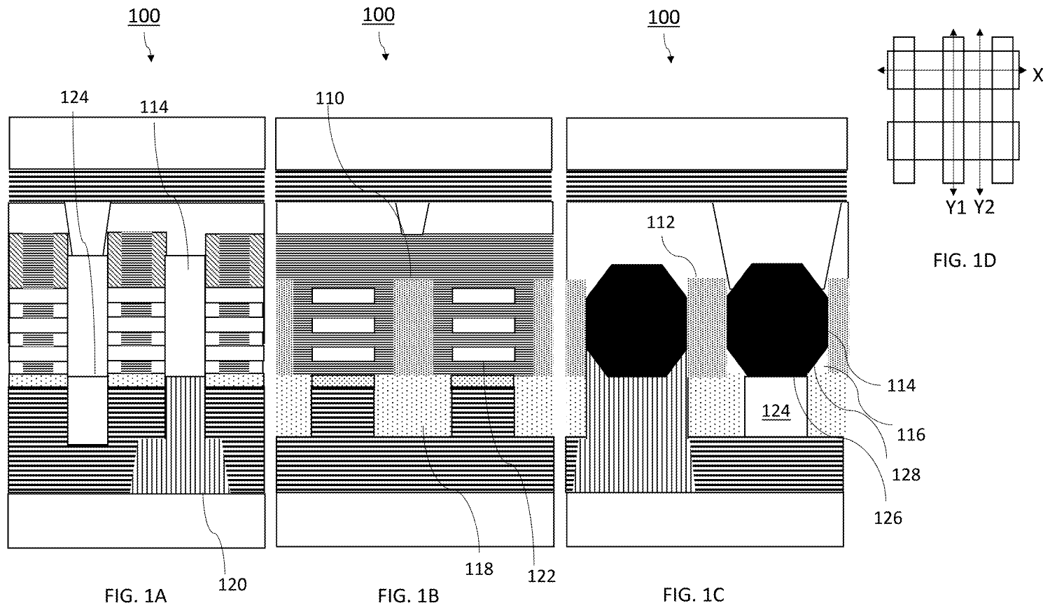

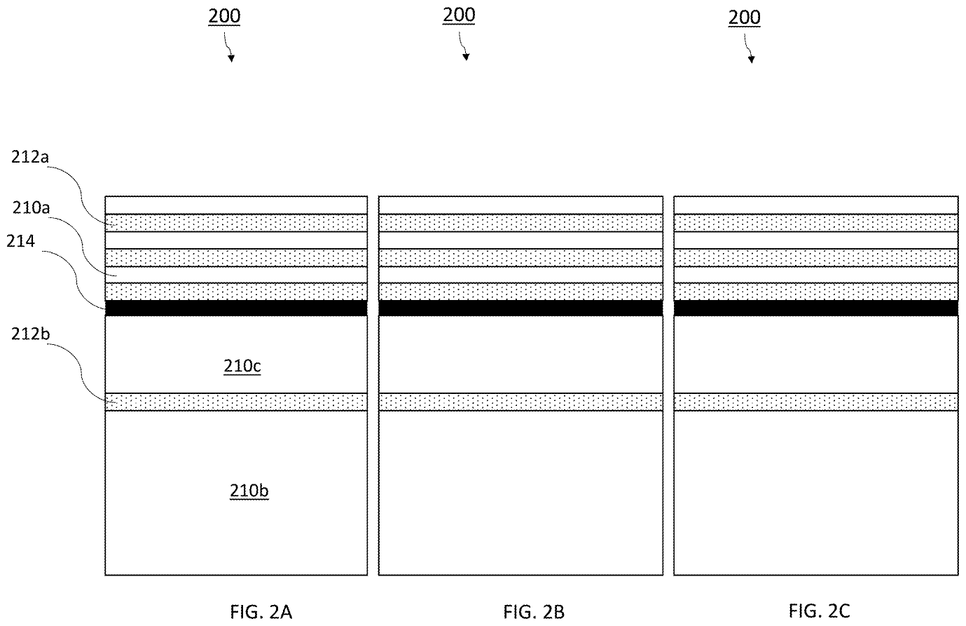

Reference now is made to FIGS. 1A-1C, which are simplified cross-section views of a semiconductor device 100, consistent with an illustrative embodiment. FIG. 1D depicts each section from which the semiconductor is shown. For example, FIG. 1A, and other figures denoted by A, illustrate an X section of the semiconductor, FIG. 1B, and other figures denoted by B, illustrate a Y1 section of the semiconductor device and FIG. 1C, and other figures denoted by C, illustrate the Y2 section of the semiconductor device.

The semiconductor device 100 can include a first dielectric bar 110, a second dielectric bar 112, source/drain regions 114, one or more airgaps 116, a shallow trench isolation (STI) 118, a backside contact area (BSCA) 120, a plurality of nanosheets 122, and a placeholder 124.

The first dielectric bar 110 between two source/drain regions 114 in the semiconductor device 100C serves as an isolation structure or spacer to separate the source and drain regions 114 electrically and physically. Similarly, the second dielectric bar 112 between the plurality of nanosheets 122 serves as an isolation structure or spacer to separate the plurality of nanosheets 122 physically. The first and second dielectric bars 110 and 112 act as electrical insulators, preventing electrical contact or short circuits between the source and drain regions 114, and the plurality of nanosheets 122, respectively. This isolation can ensure that the current flows only through the desired channel region, or nanosheets, and avoids unintended leakage or interference.

In some embodiments, the first dielectric bars 110 can further help define and control the effective channel length of the semiconductor device 100. Typically, the channel length refers to the region between the source and drain regions where the current flows when the semiconductor device is in the “ON” state. By accurately positioning the first dielectric bar 110, the channel length can be precisely controlled, influencing the semiconductor device's electrical characteristics, such as current modulation and switching behavior.

In several embodiments, the presence of the first and second dielectric bars 110 and 112 between the source/drain regions 114 and the plurality of nanosheets 122 can help reduce parasitic capacitance. Parasitic capacitance can adversely impact device performance, causing delays, power consumption, and signal integrity issues. In such embodiments, the first and second dielectric bars 110 and 112 can act as physical spacers, increasing the separation between the gate and the source/drain regions 114 and the plurality of nanosheets 122, respectively, thereby minimizing parasitic capacitance.

In an embodiment, the first and second dielectric bars 110 and 112 further aid in optimizing the doping profile of the channel region. By controlling the placement and dimensions of the first and second dielectric bars 110 and 112, the dopant diffusion during subsequent processing steps can be precisely controlled, which enables more accurate control over the doping concentration and distribution in the channel region, optimizing the semiconductor device's electrical properties and performance.

Generally, the source/drain regions are two salient components that play relevant roles in the semiconductor device's operation. Typically, source/drain regions are regions within the semiconductor material, e.g., the semiconductor device 100, where the current flows in and out of the transistor. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

The airgap 116 can be a deliberate void or empty space created within the semiconductor device 100, between the first dielectric bar 110 and the source/drain regions 114. In various embodiments, each of the source/drain regions 114 has a filleted shape. As shown in FIGS. 1-20, the source/drain regions can have an octagonal shape, although other shapes, such as diamond and hexagonal shapes, are possible. In such embodiments, a bottom portion of the source/drain region 114 includes a horizontal bottom surface 126 connecting two sloped surfaces 128. The airgap 116 can be formed within the space between each of the two sloped surfaces 128 and the second dielectric bar 112. Forming the airgap 116 instead of filling it with any other material can lower the dielectric constant of the airgap region, and the semiconductor device 100 as a whole, since the air has a significantly lower dielectric constant compared to typical semiconductor materials or insulating layers. Thus, by incorporating the airgap 116, the effective dielectric constant of the semiconductor device 100 can be reduced. Such a reduction can result in improved semiconductor device performance, as it reduces parasitic capacitance, enhances signal speed, and lowers power consumption.

In some embodiments, the presence of the airgap 116 can help minimize parasitic capacitance between adjacent conducting lines or circuit elements, which can affect signal propagation delay and crosstalk. By forming the airgap 116, the capacitance between neighboring conductors can be reduced, signal integrity can be enhanced, and unwanted coupling between signals can be minimized.

In an embodiment, the airgap 116, as a poor conductor of heat compared to solid materials, can provide thermal isolation between different components or regions of a semiconductor device 100, i.e., the source/drain regions 114 and the second dielectric bar 112. This isolation can help prevent the transfer of heat between adjacent structures, improve thermal management, reduce temperature rise, and enhance device reliability.

In additional embodiments, the airgap 116 can further help mitigate mechanical stress or strain within the semiconductor device 100. Thermal expansion mismatch, differences in material properties, or stress-inducing fabrication processes can result in mechanical stress. The airgap 116 can act as a stress buffer, absorb and reduce the impact of mechanical strain, hence enhancing the semiconductor device's mechanical stability and reducing the risk of failure.

In some embodiments, the lower effective dielectric constant resulting from the presence of the airgap 116 can enhance the speed and quality of signal propagation within the semiconductor device 100. The reduced capacitance and improved signal integrity contribute to faster signal rise and fall times, reduced signal delay, and improved overall device performance.

The STI 118 includes shallow trenches in the semiconductor device 100 filled with insulating materials to form isolation structures. The STI 118 can provide electrical isolation between adjacent transistors or components within the semiconductor device 100. The STI 118 can prevent electrical interference, leakage, and crosstalk, ensuring that the semiconductor device 100 operates independently and reliably. In an embodiment, STI 118 can help reduce parasitic capacitance between adjacent transistors. The STI 118 also can prevent latch-up, a condition where a parasitic thyristor-like structure causes unintended device behavior. The STI 118 can further interrupt the formation of the parasitic p-n-p-n structure, enhancing device reliability. The backside contact 120 is the electrical connection made to the backside or substrate region of the semiconductor device 100 and can be a metal contact on the backside of the semiconductor device 100 to establish electrical connectivity with the substrate.

In some embodiments, the backside contact 120 can facilitate the grounding of the substrate, ensuring a stable reference potential for the semiconductor device 100. Further, the backside contact 120 can help minimize parasitic effects in the semiconductor device 100, such as substrate coupling, stray capacitance, and leakage currents. By establishing a direct electrical connection to the substrate, such parasitic effects can be mitigated, leading to improved device performance and reliability. Even further, the backside contact 120 can aid in thermal dissipation by providing a pathway for heat transfer from the semiconductor device 100 to external cooling mechanisms.

The plurality of nanosheets 122 can include three-dimensional structures in the gate metal, which are extended from the source region towards the drain region. Each nanosheet can include one or more layers.

In order to form the backside contact 120, portions of the semiconductor device 100, i.e., the substrate, need to be removed. However, inaccurate substrate removal can lead to forming a cavity that does not match the desired backside contact 120. Thus, in some embodiments, the placeholder 124 is formed under at least one of the source/drain regions 114. In some embodiments, a sacrificial placeholder is formed, which is later removed and replaced by the backside contact 120.

### Example Processes for Tunnel Nanosheet FET Structures

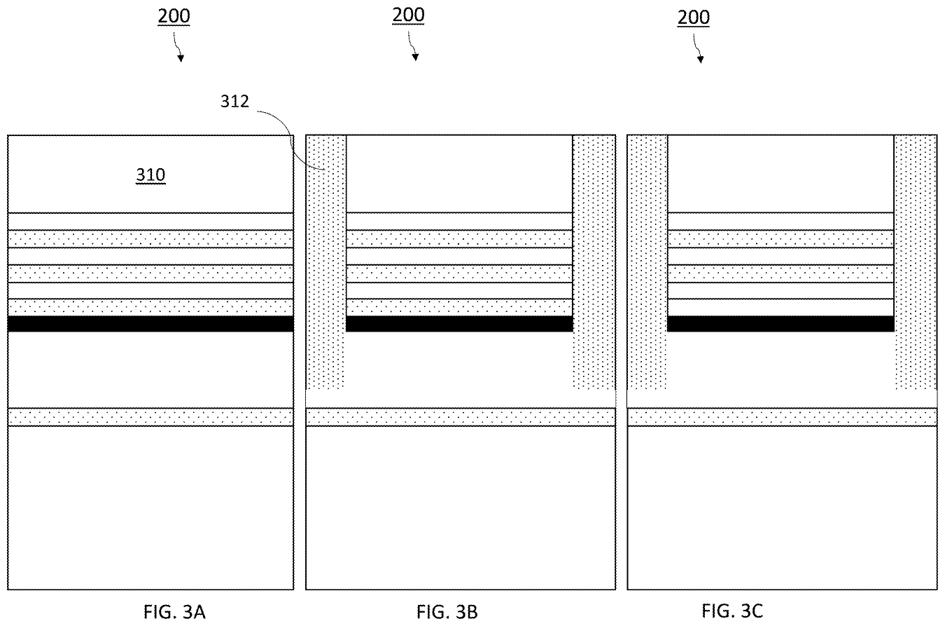

With the foregoing description of an example semiconductor device 200, it may be helpful to discuss an example process of manufacturing the same. To that end, FIGS. 2-20 illustrate various steps in the manufacture of a semiconductor device 200, consistent with illustrative embodiments. As noted above, figures denoted by A, B, and C illustrate a step of fabrication of the semiconductor device 100 from a different point of view. It is also worth mentioning that the semiconductor 100 depicted in FIGS. 1A-1C can be the same as the semiconductor 200 depicted in FIGS. 2-20.

Referring to FIGS. 2A-2C now, a semiconductor device 200 after the formation of the alternating layers of Si and SiGe layers over a substrate is shown, consistent with an illustrative embodiment. The first active layer can include alternating layers of Si and SiGe 210a and 212a to be used to form the plurality of nanosheets, formed over a first substrate 210b.

In the illustrative example depicted in FIGS. 2A-2C, the semiconductor device 200 is depicted as being on silicon as a first substrate 210b, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 210b may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, an etch stop layer 212b is formed over the first substrate 210b. The etch stop layer 212b can be a thin layer of material incorporated into the structure of the semiconductor device 200 to provide a selective barrier against etching processes, preventing further removal of underlying materials during fabrication. The etch stop layer 212b can enable precise control over the etching depth and helps define the desired device dimensions. The etch stop layer 212b can further provide a stopping point for the etching process, ensuring that specific layers or regions are not etched beyond a certain point, leading to accurate patterning and control of critical features. The etch stop layer 212b can create a distinct separation between different layers or components within the device structure, and prevent the undesired etching of underlying layers or materials, enabling the creation of complex, multi-layered structures with well-defined interfaces and boundaries. In some embodiments, the etch stop layer 212b acts as a protective barrier for sensitive or delicate materials to shield such materials from aggressive etchants, preventing damage or degradation during subsequent fabrication steps.

In some embodiments, prior to forming the etch stop layer 212b, the first substrate 210b is prepared by cleaning and removing any impurities or oxide layers. The etch stop layer 212b is deposited onto the first substrate 210b using techniques such as epitaxy growth. The etch stop layer 212b can then be selectively etched, stopping at a predetermined depth, while protecting the underlying layers.

While in some embodiments, SiGe is used to form the etch stop layer 212b, in some embodiments, silicon oxide (SiO₂), silicon nitride (SiN) or silicon oxynitride (SiON) can be used as the etch stop layer 212b. In some embodiments, a second substrate layer 210c is epitaxially grown over the etch stop layer 212b.

The alternating layers of Si and SiGe 210a and 212a can be heavily doped with donor impurities such as phosphorus or arsenic to provide an excess of electrons in an n-type semiconductor device 200. Similarly, in some embodiments, the alternating layers of Si and SiGe 210a and 212a can be heavily doped with acceptor impurities such as boron or gallium.

A SiGe layer 214 can be formed over the second substrate 210c. The SiGe layer 214 can have a higher concentration of Ge compared to the SiGe layers 212a. In an embodiment, the Ge content of the SiGe 214 is about 55% Ge.

The alternating layers of Si and SiGe 210a and 212a can be deposited using techniques such as thermal oxidation, CVD, PVD.

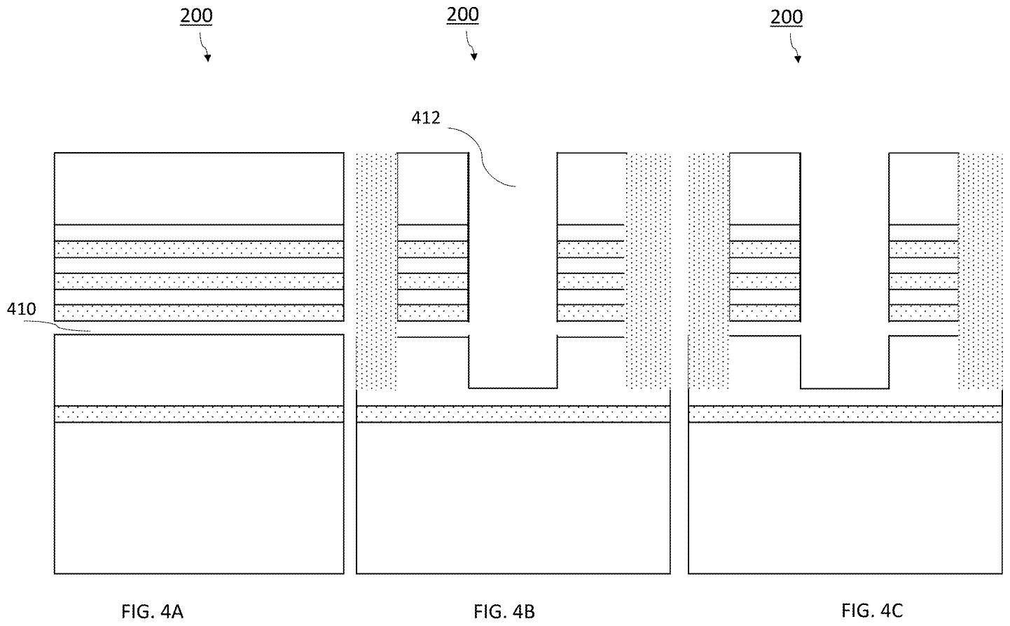

FIGS. 3A-3C illustrate side-views of a semiconductor device 200 after the patterning of a first active layer, in accordance with some embodiments. The active layer patterning can include forming a hard mask 310 and an interlayer dielectric, ILD, 312. The hard mask 310 can be a thin layer of material to act as a protective layer and to enable precise pattern transfer to the underlying layers during various fabrication steps and aid in pattern transfer. The hard mask 310 can act as a template for defining the desired patterns on the underlying layers, and provide a protective layer that withstands subsequent etching or deposition processes, ensuring precise pattern transfer with high fidelity. In various embodiments, the hard mask 310 resists etchants that are aggressive towards the underlying layers, preventing their undesired removal or damage. In additional embodiments, the hard mask 310 serves as a barrier between different fabrication steps, allowing compatibility with subsequent processes.

In order to form the hard mask 310, the hard mask material is deposited onto the semiconductor device 200 using techniques such as CVD, PVD, or ALD. Silicon nitride (SiN) and silicon oxide (SiO2) can be used as hard masks.

The ILD 312 can be a layer of insulating material to electrically isolate and provide mechanical support between different layers of conducting and active components. The ILD 312 can enable efficient signal transmission, reduce crosstalk, and ensure the proper functioning of the semiconductor device 200. The ILD 312 can electrically isolate adjacent conducting layers or active components in the semiconductor device 200. By providing insulation between different layers, the ILD 312 prevents electrical shorts, minimizes leakage current, and ensures that signals are directed only along the desired pathways. In some embodiments, the ILD 312 can help reduce parasitic capacitance between adjacent metal interconnects or active devices and provide mechanical support to the integrated circuit structure.

The ILD 312 can be deposited onto the substrate using various techniques such as CVD, spin-on deposition, plasma-enhanced CVD (PECVD), or ALD. In some embodiments, after deposition, planarization techniques are employed to ensure a flat and smooth surface. In an embodiment, chemical mechanical polishing (CMP) can be used to remove excess material and achieve a uniform surface topography. In some embodiments, silicon dioxide (SiO2), or a low-k dielectric, e.g., organosilicates, fluorinated silicates, or porous materials, can be used as ILD 312. Alternatively, polymer-based materials, such as polyimide or polybenzoxazole (PBO), can be used as ILD 312.

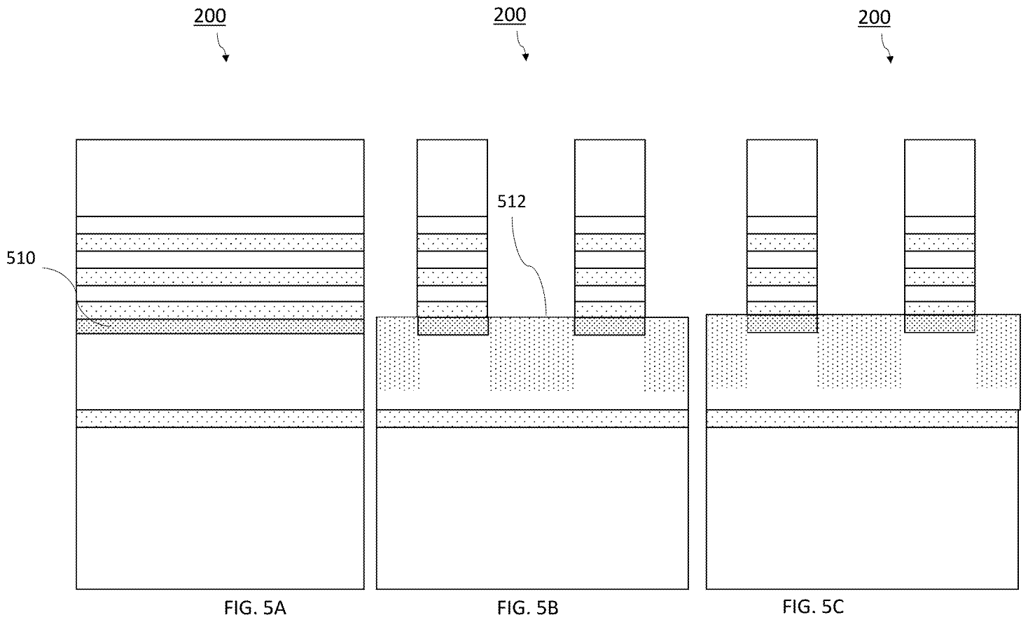

FIGS. 4A-4C illustrate side-views of a semiconductor device 200 after the patterning a second active layer, in accordance with some embodiments. In some embodiments, portions of the hard mask, the alternating layers of Si layers and SiGe, and the second substrate are removed, forming a cavity 412. In addition, the high-Ge SiGe is removed, forming a horizontal cavity layer 410. In some embodiments, the high-Ge SiGe is removed by an etching process.

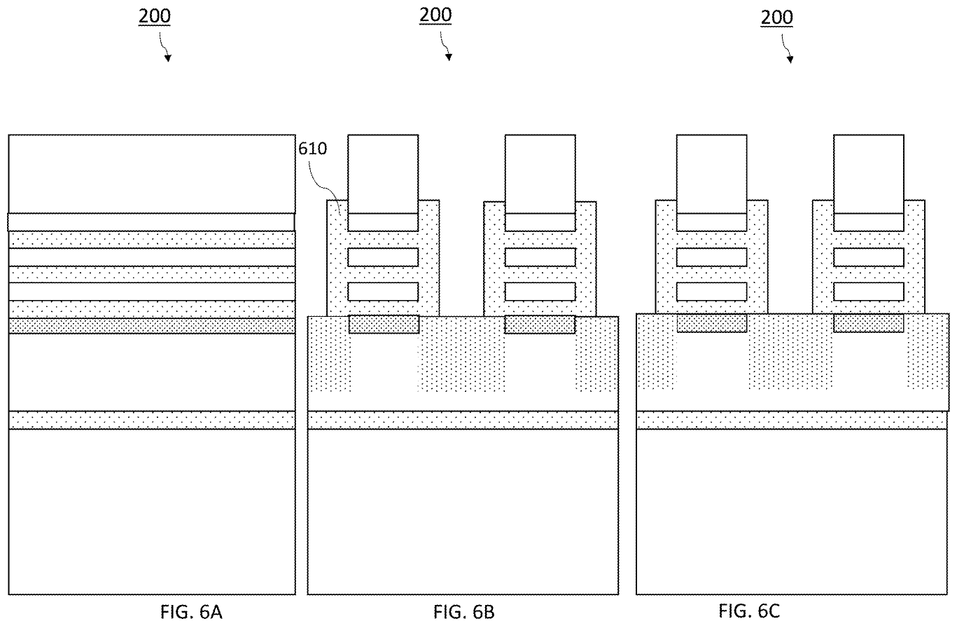

FIGS. 5A-5C illustrate side-views of a semiconductor device 200 after the self-aligned substrate isolation is formed, in accordance with some embodiments. The semiconductor device 200 can include self-aligned substrate isolation, SASI, 510, which can be utilized to isolate the semiconductor structure from the substrate electrically. The SASI 510 can provide isolation and reduce parasitic capacitance and leakage currents between the semiconductor device 200 and the substrate layer. The SASI 510 is a dielectric material that can help improve the semiconductor device 200 performance and reliability by minimizing undesirable effects such as substrate leakage and latch-up. In some embodiments, portions of ILD are removed. Thus, the sidewalls of the alternating layers of Si and SiGe are exposed. In some embodiments, the portions of ILD are removed by an etching process. Additionally, a layer of ILD fills the portion of the cavity within the second Si substrate to form shallow trench isolation, STI 512.

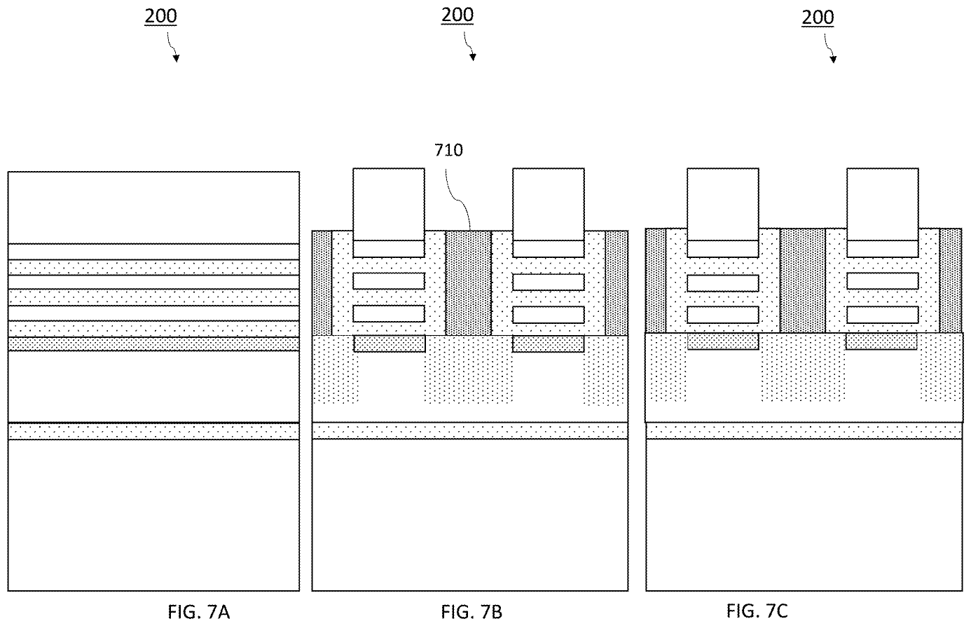

FIGS. 6A-6C illustrate side-views of a semiconductor device after sidewall spacer formation, in accordance with some embodiments. In some embodiments, the sidewalls of the alternating layers of Si and SiGe are covered by a sidewall spacer 610 to define a gate extension region. The sidewall spacer 610 can be formed by deposition and etching techniques. Alternatively, the sidewall spacer 610 can be formed by selectively epitaxially growing the sidewall spacer 610 over the sidewalls of the alternating layers of Si and SiGe. In various embodiments, the sidewall spacer 610 can include SiGe.

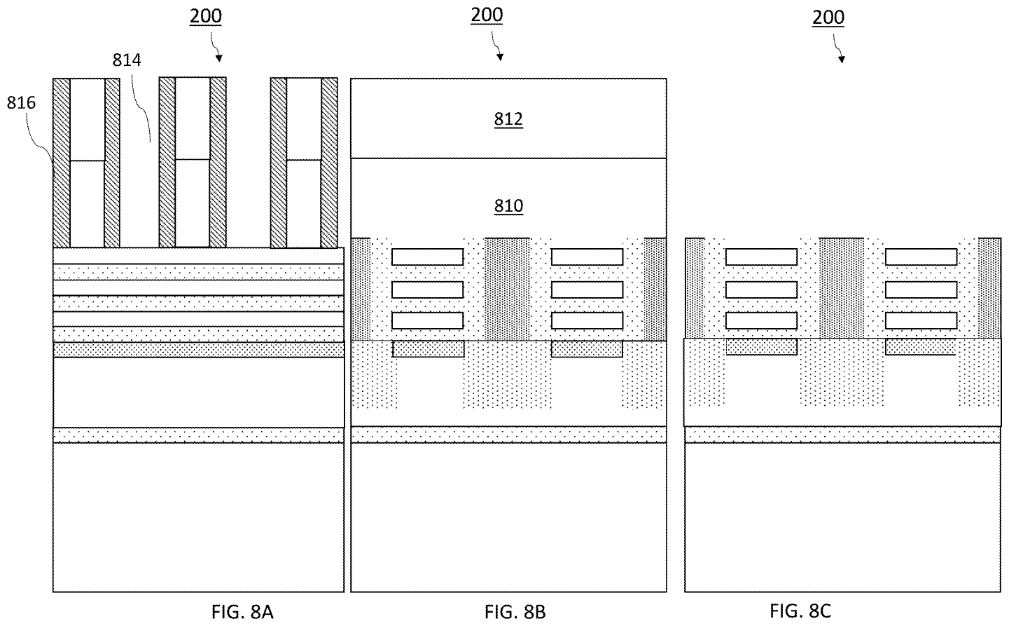

FIGS. 7A-7C illustrate side-views of a semiconductor device after the dielectric bars are formed, in accordance with some embodiments. In some embodiments, the dielectric bar 710 can be formed in the cavity between the stacks of SiGe-covered alternating layers of Si and SiGe and over the STI.

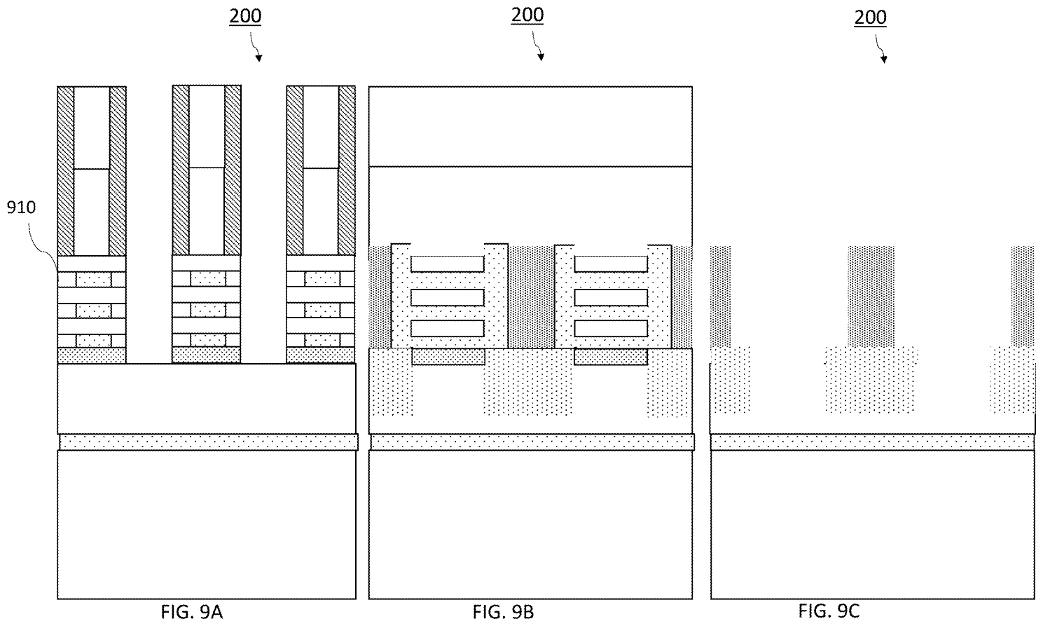

FIGS. 8A-8C illustrate side-views of a semiconductor device after the gate is patterned, in accordance with some embodiments. In some embodiments, the hard mask is removed, so the top surface of the alternating layers of Si and SiGe are exposed. A dummy gate 810 is formed above the alternating layers of Si and SiGe, followed by forming a hard mask 812 over the dummy gate 810. Subsequently, portions of the dummy gate-hard mask layer are removed to form cavities 814 between the dummy gate-hard mask layer. A gate spacer 816 is formed within each cavity 814 and over the sidewalls of the dummy gate-hard mask layer.

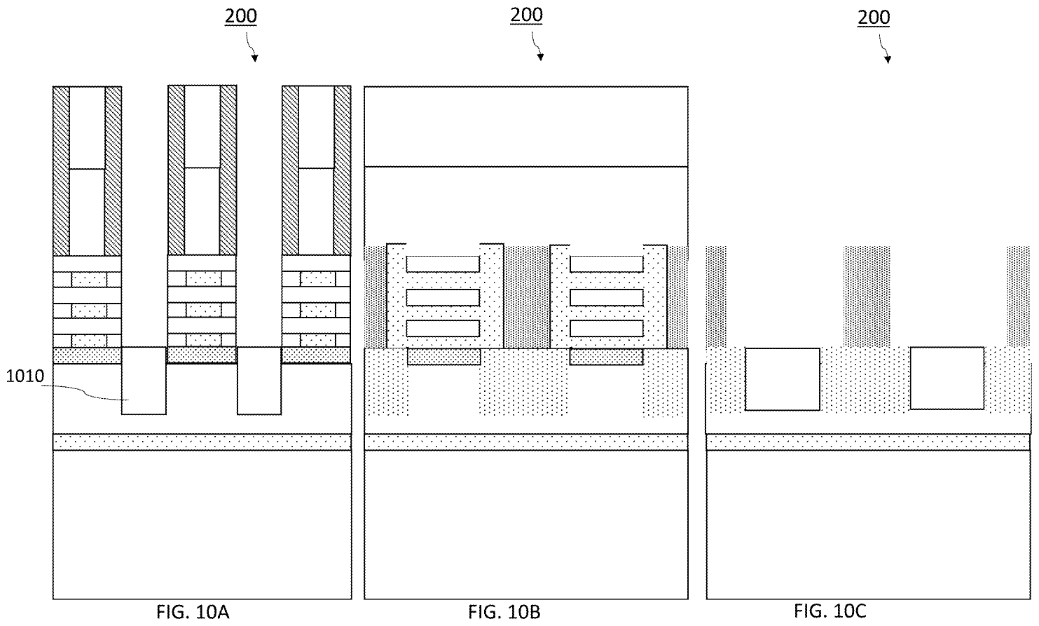

FIGS. 9A-9C illustrate side-views of a semiconductor device after nanosheets are recessed, and the inner spacer is formed. In an embodiment, the cavities between the dummy gate-hard mask layer are recessed to form a plurality of nanosheets which includes the alternating layers of Si and SiGe. The sidewalls of the SiGe layers of the alternating layers of Si and SiGe are further indented and covered by the inner spacer 910. After this step, the cavities are vertically extended from the top of the semiconductor device 200 down to the top surface of the second substrate. As can be seen, while the portion of the alternating layers of Si and SiGe under dummy gate-hard mask layer remains over the Y1 section of the semiconductor device 200, the portions of the alternating layers of Si and SiGe under dummy gate-hard mask layer over the Y2 section of the semiconductor device 200 are removed.

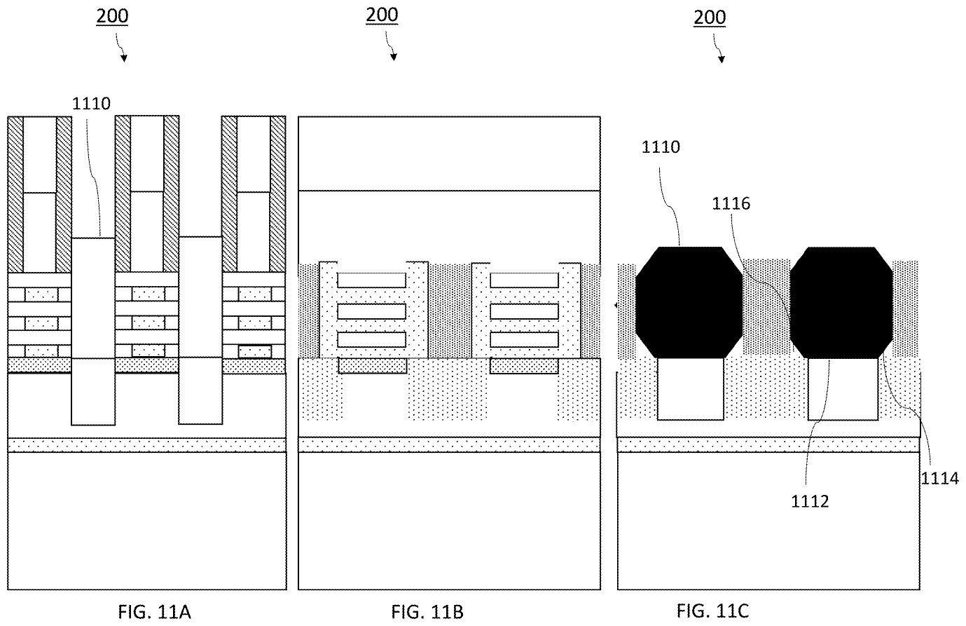

FIGS. 10A-10C illustrate side-views of a semiconductor device after the placeholder is grown, in accordance with some embodiments. In some embodiments, the cavity between the dummy gate-hard mask can be further extended inside the second substrate. That is, a new cavity, which is an extension of the cavity between the dummy gate-hard mask, is formed within the second substrate. The cavity within the second substrate can be formed by a reactive ion etching (RIE) technique. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device 200 inside a vacuum chamber. The chamber is then evacuated to create a low-pressure environment. Reactive gases, which can consist of a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment. In some embodiments, Radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected. In some embodiments, to achieve selective etching, an etch mask can be applied on the substrate surface prior to the RIE process. The etch mask protects certain regions from etching, allowing the reactive ions to remove the exposed material selectively.

The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants. Subsequently, the cavity within the second substrate can be filled with a placeholder 1010. The placeholder 1010 can be epitaxially grown.

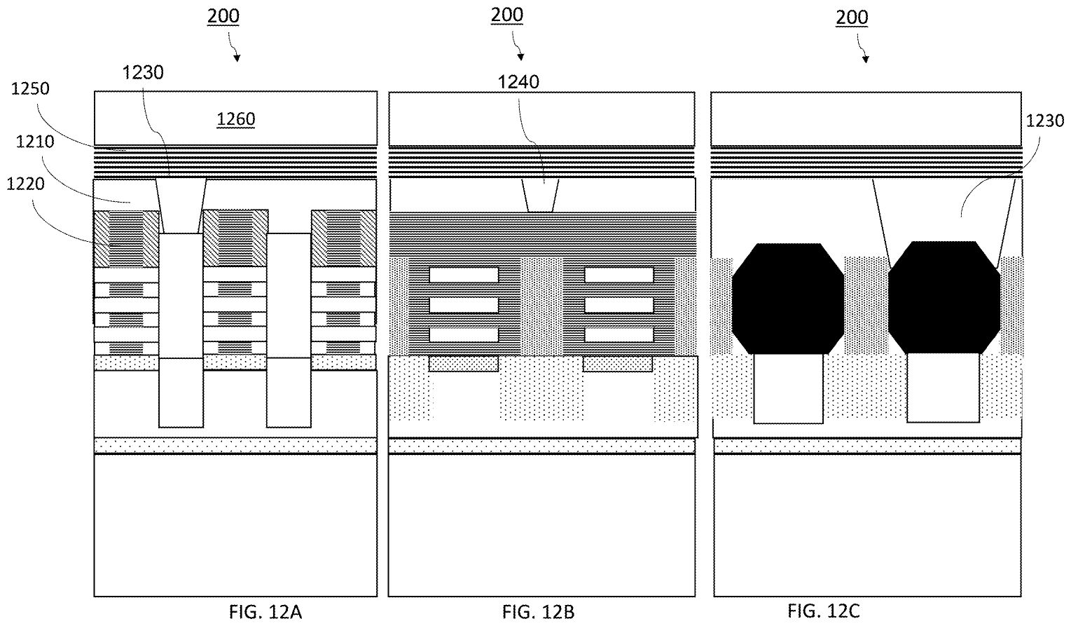

FIGS. 11A-11C illustrate side-views of a semiconductor device after growing the source and drain regions, in accordance with some embodiments. In various embodiments, the source/drain regions 1110 are formed in the cavities between the dielectric bars. Each source/drain region 1110 can be in contact with the dielectric bars on both sides and the placeholder on a bottom surface. Further, the source/drain region 1110 can have an octagonal shape. That is, the bottom portion of the source/drain region 1110 can include a horizontal bottom surface 1112 connecting two sloped surfaces 1114. While the horizontal bottom surface 1112 can be in contact with the placeholder in its entirety, only the two edges of each of the sloped surfaces 1114 are in contact with the placeholder and the dielectric bar, respectively. Thus, an airgap 1116 can be formed in the bottom corner between each source/drain region 1110, the dielectric bar, and the placeholder. The airgap 1116 can be sealed by the dielectric bars. Since the air has a significantly lower dielectric constant compared to other materials or insulating layers in the semiconductor device 200, incorporating the airgap 1116 can reduce the effective dielectric constant of the semiconductor device 200, which can result in an improved semiconductor device 200 performance, as it reduces parasitic capacitance, enhances signal speed, and lowers power consumption. Further, the presence of the airgap 1116 can help minimize parasitic capacitance, which affects signal propagation delay and crosstalk, between adjacent conducting lines or circuit elements. In some embodiments, the airgap 1116 can provide thermal isolation between different components or regions of the semiconductor device 200. Such isolation can help prevent the transfer of heat between adjacent structures, improving thermal management, reducing temperature rise, and enhancing device reliability.

In some embodiments, the airgap 1116 can mitigate mechanical stress or strain within the semiconductor device 200. Thermal expansion mismatch, differences in material properties, or stress-inducing fabrication processes can result in mechanical stress. Airgap 1116 can act as a stress buffer, thus, absorbing and reducing the impact of mechanical strain, which can enhance the semiconductor device's mechanical stability and reduce the risk of failure. In some embodiments, the lower effective dielectric constant resulting from the presence of the airgap 1116 can enhance the speed and quality of signal propagation within the semiconductor device 200, as the reduced capacitance and improved signal integrity can contribute to faster signal rise and fall times, reduced signal delay, and improved overall device performance.

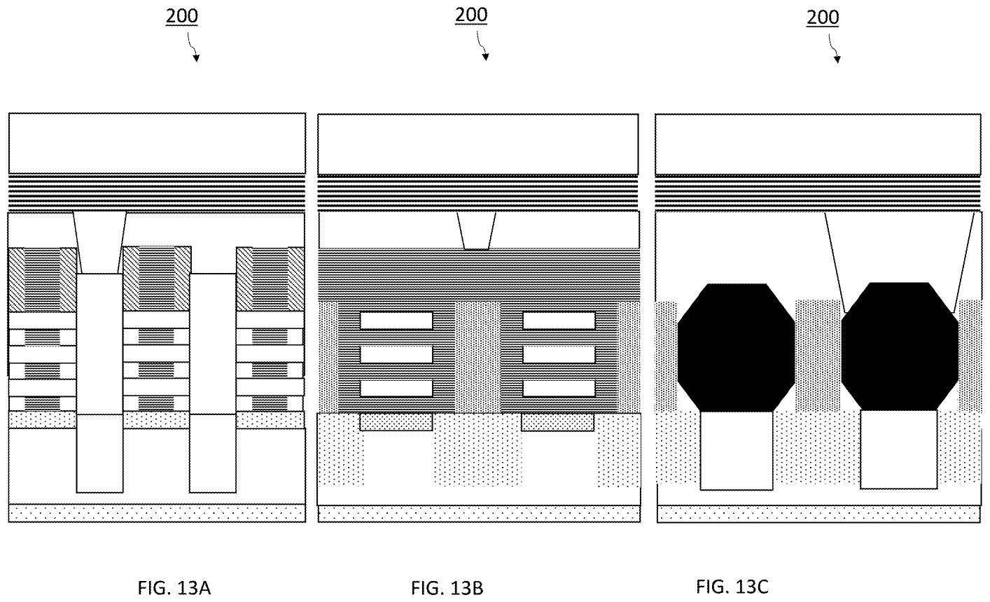

FIGS. 12A-12C illustrate side-views of a semiconductor device after the wafer bonding, in accordance with some embodiments. In some embodiments, the ILD 1210 can be formed by a deposition technique, followed by a CMP process. Afterward, the dummy gate is removed, and the SiGe in the alternating layers of Si and SiGe is released. A replacement metal gate (RMG) process can be used to fabricate metal gate region 1220. RMG can involve the replacement of the SiGe with a metal material, which can offer improved electrical performance and scalability. The metal gates can provide electrostatic control of the channel region, reduce leakage currents and improve the semiconductor device's performance. In some embodiments, the metal gates can further provide improved control over the work function and enable matching of threshold voltages and reduce semiconductor device variability.

Once the RMG process is finished, the middle of the line (MOL) source/drain contact 1230 and gate contact 1240 and the back end of the line, BEOL 1250, are formed. In various embodiments, carrier wafer 1260 bonding, also known as wafer-to-wafer bonding or chip-to-wafer bonding, is performed to join two wafers together by creating a permanent bond between them. In some embodiments, the two wafers can be brought into contact and bonded at the atomic or molecular level, to create an interface. In an embodiment, the two wafers are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One wafer can be made of semiconductor material, while the other can compose of a glass or silicon dioxide (SiO2) layer. The electric field can cause ions in the glass or SiO2 to migrate and chemically bond with the semiconductor material in the other wafer. In additional embodiments, a thin metal layer or metal alloy can be used as an intermediate bonding layer between the wafers. The metal layer can be deposited or transferred onto one or both wafers, and the wafers can then be brought into contact and subjected to temperature and pressure to create a metallic bond.

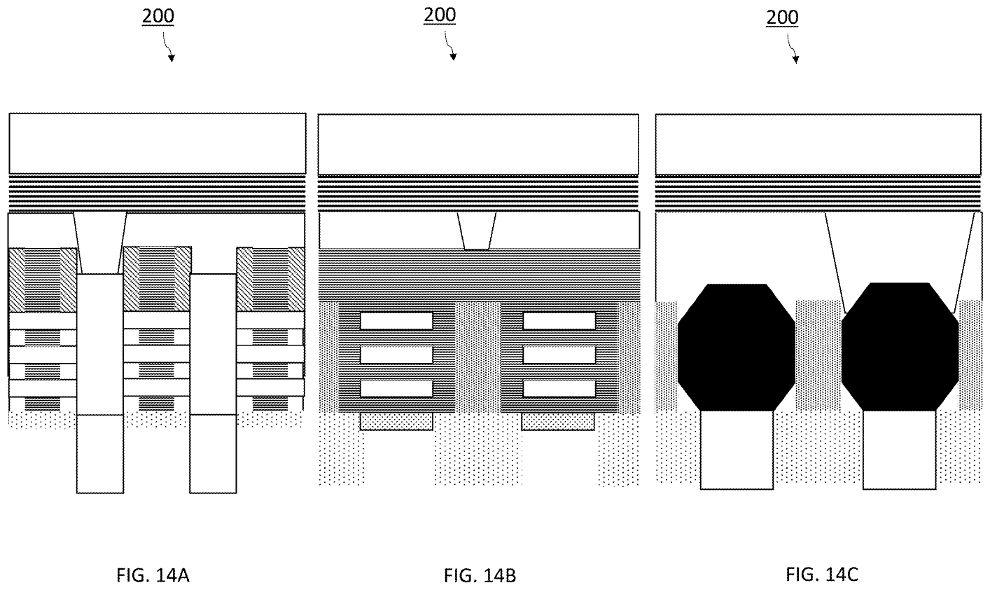

FIGS. 13A-13C illustrate side-views of a semiconductor device after the substrate is removed, in accordance with some embodiments. In some embodiments, the wafer is flipped, and the first substrate is removed. The first substrate removal process can proceed until reaching the etch stop layer. It should be noted that, for the sake of simplicity, the semiconductor device 200 is not shown are flipped.

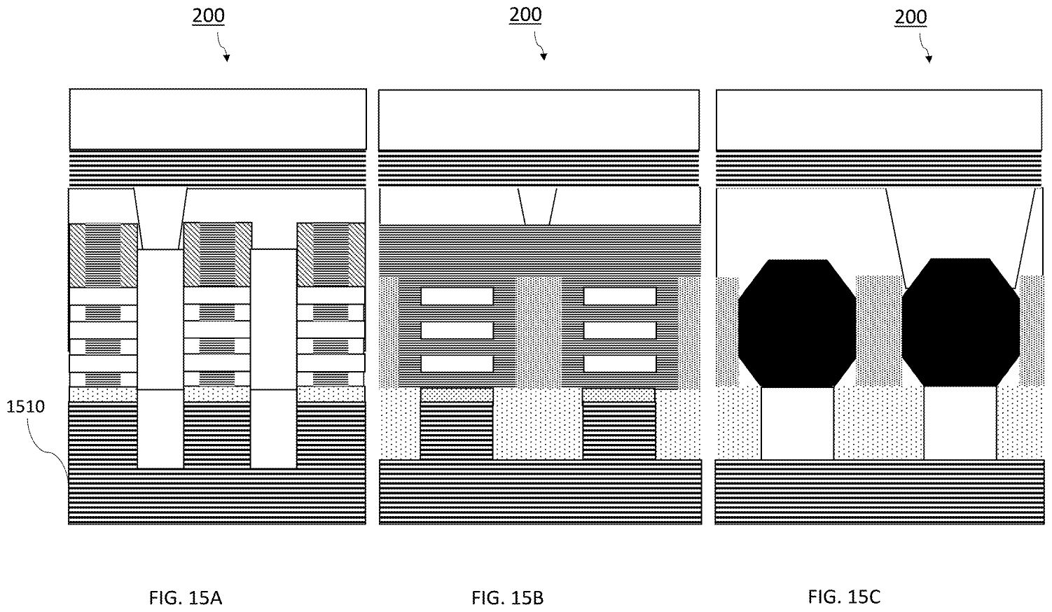

FIGS. 14A-14C illustrate side-views of a semiconductor device after the etch stop layer is removed, in accordance with some embodiments. In some embodiments, the etch stop layer is removed, followed by removing the remaining substrate, i.e., the second substrate.

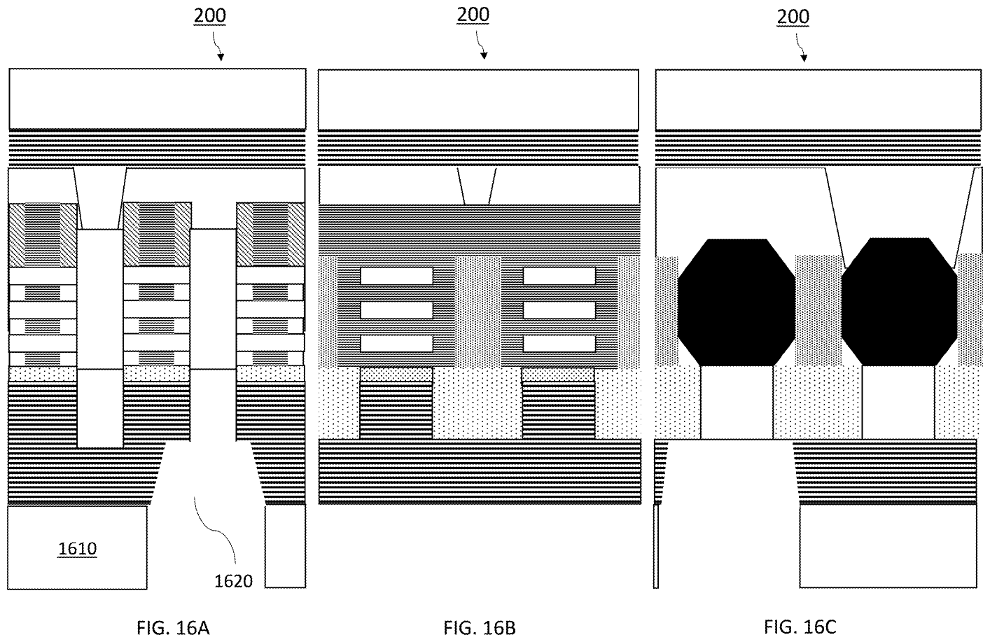

FIGS. 15A-15C illustrate side-views of a semiconductor device after the backside ILD is deposited, in accordance with some embodiments. In some embodiments, the backside ILD, BILD 1510, is formed below the STI, the placeholder, and the SASI. In various embodiments, the materials used to form the BILD 1510 is different from the material used to form SASI, dielectric bar, and STI. As a non-limiting example, the materials used to form the BILD 1510 can include SiC and SiOC.

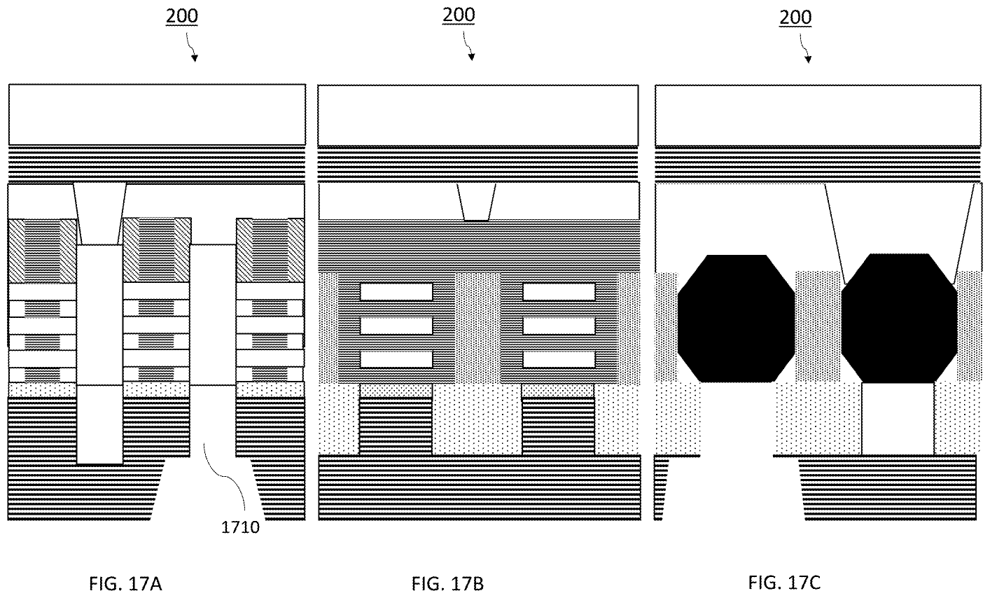

FIGS. 16A-16C illustrate side-views of a semiconductor device after the backside contact is patterned, in accordance with some embodiments. In some embodiments, an organic planarization layer, OPL 1610, is formed under the BILD. The OPL 1610 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylene ether resin, polyphenylene sulfide resin, or benzo-cyclobutene (BCB). In some embodiments, the OPL 1610 can include any organic polymer and a photoactive compound having a molecular structure that can attach to the molecular structure of the organic polymer. In some embodiments, the OPL 1610 material is selected to be compatible with an overlying antireflective coating (not shown) and/or an overlying photoresist (not shown). In some embodiments, the OPL 1610 can be applied using spin coating technology, although other techniques are within the contemplated scope of the present disclosure. Once the OPL 1610 is formed, the backside contact patterning is performed to form a recess 1620 within the OPL 1610 and the BILD to reach the bottom surface of the placeholder.

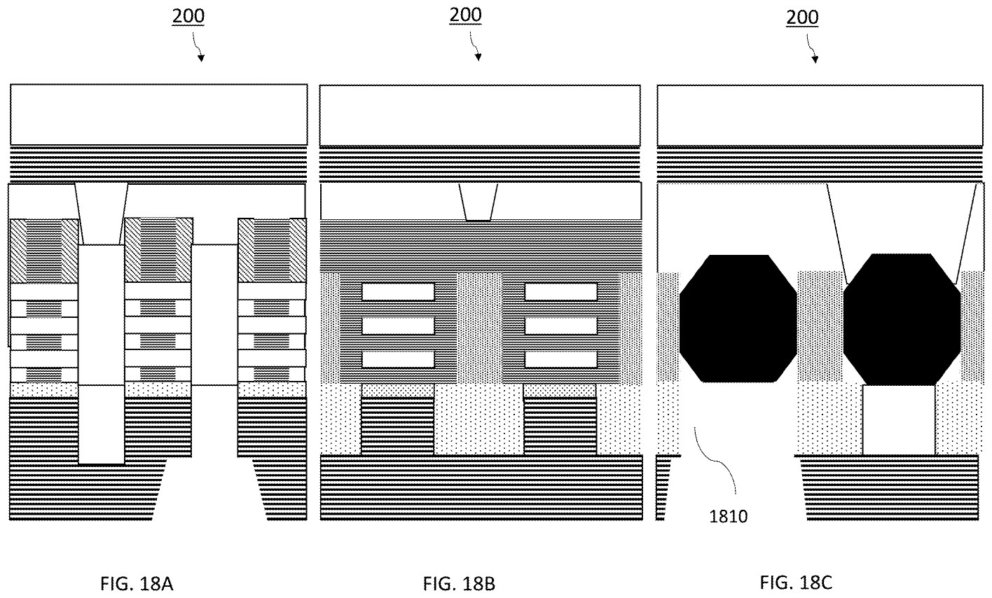

FIGS. 17A-17C illustrate side-views of a semiconductor device after the sacrificial placeholder is removed, in accordance with some embodiments. In some embodiments, once the recess is formed, the OPL is removed. In some embodiments of the present disclosure, the OPL can be removed using, for example, ashing or any other suitable removal technique. Further, a placeholder can be removed so that recess 1710 is extended to the bottom of the source/drain region.

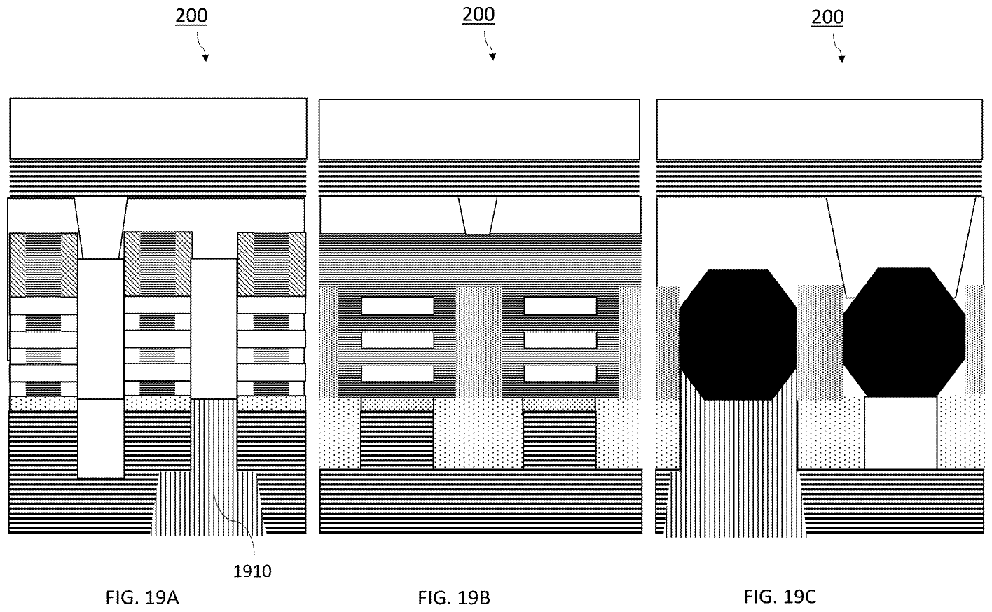

FIGS. 18A-18C illustrate side-views of a semiconductor device after the STI is etched, in accordance with some embodiments. In some embodiments, the STI is isotropically removed via an etching process that does not affect the BILD. As a result, the recess is widened to form a larger recess 1810 that matches the bottom surface of the source/drain region.

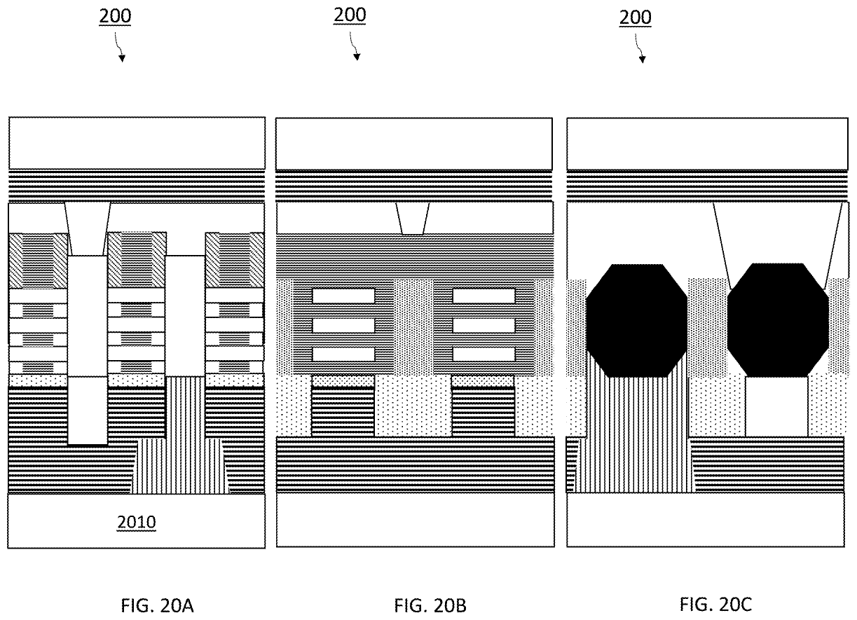

FIGS. 19A-19C illustrate side-views of a semiconductor device after the backside contact metallization, in accordance with some embodiments. In some embodiments, the BSCA 1910 is formed within the recess by filling by a metal contact. As a result, the airgap is filled with the BSCA 1910, and the bottom portion of the source/drain region is wrapped around by the BSCA 1910. In some embodiments, only the backside source/drain region is wrapped around with the BSCA 1910, and the airgap in the frontside source/drain region that is connected to MOL contact 1240 remains intact.

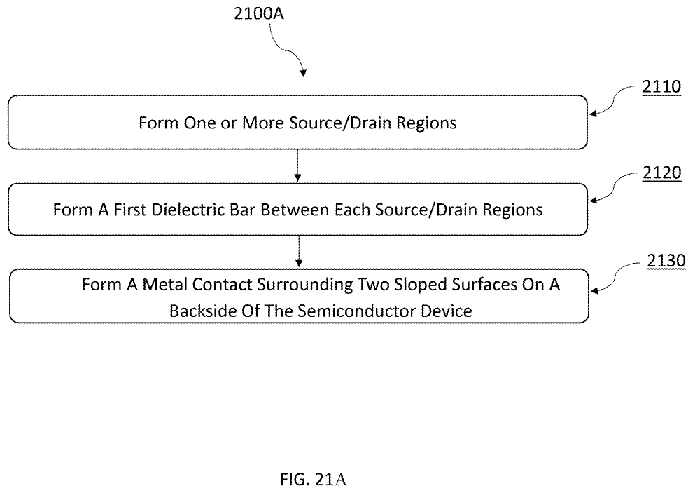

FIGS. 20A-20C illustrate side-views of a semiconductor device after the backside interconnect formation, in accordance with some embodiments. In some embodiments, a backside interconnect 2010 can be formed under the BILD, STI, SASI, and BSCA.

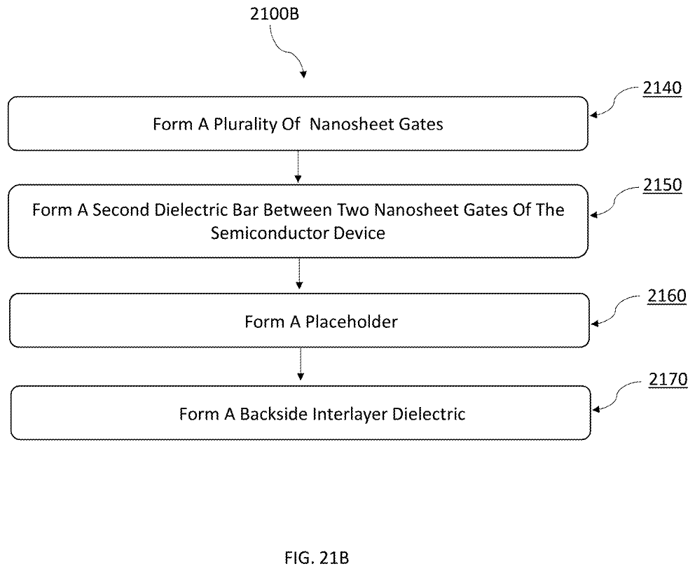

FIGS. 21A-21B illustrate block diagrams of a method 2100A for forming the semiconductor device, in accordance with some embodiments. Referring to FIG. 21A now, the method 2100A can begin when one or more source and drain regions above a substrate layer are formed, as shown by block 2110. In some embodiments, each of one or more source and drain regions has a filleted, e.g., an octagonal shape. Additionally, the bottom portion of the filleted shape includes a horizontal bottom surface connecting two sloped surfaces.

In an embodiment, the method 2100A proceeds when a first dielectric bar between each of the one or more source and drain regions is formed, as shown by block 2120.

In some embodiments, the method 2100A continues when a metal contact surrounding two sloped surfaces on the backside of the semiconductor device is formed, as shown by block 2130.

Referring to FIG. 2100B now, a method 2100B for forming the semiconductor device, is shown. The method 2100B can proceed when a plurality of nanosheet gates are formed between the one or more source and drain regions, as shown by block 2140.

The method 2100B proceeds when a second dielectric bar between each two nanosheet gates of the plurality of nanosheet gates is formed, as shown by block 2150. In an embodiment, an airgap between two sloped surfaces on a frontside of the semiconductor device is formed. In some embodiments, forming the airgap can include sealing the airgap with the first dielectric bar, a shallow trench isolation layer and the nanosheet gates.

In additional embodiments, the method 2100B proceeds when a placeholder located under at least one of the one or more source and drain regions is formed, as shown by block 2160. The placeholder can be in contact with the horizontal bottom surface, but not in contact with two sloped surfaces on a frontside of the semiconductor device. In some embodiments, a first critical dimension of the metal contact is larger than a second critical dimension of the placeholder. In such embodiments, the first and second critical dimensions are extended in a first direction. Additionally, or in the alternative, in some embodiments, a third critical dimension of the metal contact is substantially equal to a fourth critical dimension of the placeholder. In such embodiments, the third and fourth critical dimensions are extended in a second direction.

In several embodiments, the method 2100B continues when a backside interlayer dielectric (BILD) located under a shallow trench isolation (STI) is formed, as shown by block 2170. In such embodiments, the BILD includes materials different than the STI, a self-aligned substrate isolation layer, and a gate isolation layer.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, the semiconductor device comprising:
one or more source and drain regions above a substrate layer, each of the one or more source and drain regions having a filleted shape, wherein a bottom portion of the filleted shape includes a horizontal bottom surface connecting two sloped surfaces; and
a first dielectric bar between each of the one or more source and drain regions,
wherein two sloped surfaces on a backside of the semiconductor device are surrounded by a metal contact.

2. The semiconductor device of claim 1, further comprising:
a plurality of nanosheet gates extended between the one or more source and drain regions; and
a second dielectric bar between each of two nanosheet gates of the plurality of nanosheet gates.

3. The semiconductor device of claim 1, further comprising an airgap between two sloped surfaces on a frontside of the semiconductor device.

4. The semiconductor device of claim 3, wherein the airgap is sealed by the first dielectric bar, a shallow trench isolation layer and a gate.

5. The semiconductor device of claim 1, further comprising a placeholder located under at least one of the one or more source and drain regions.

6. The semiconductor device of claim 5, wherein:
the placeholder is in contact with the horizontal bottom surface; and
the placeholder is not in contact with two sloped surfaces on a frontside of the semiconductor device.

7. The semiconductor device of claim 5, wherein:
a first critical dimension of the metal contact is larger than a second critical dimension of the placeholder; and
the first and second critical dimensions are extended in a first direction.

8. The semiconductor device of claim 5, wherein:
a third critical dimension of the metal contact is substantially equal to a fourth critical dimension of the placeholder; and
the third and fourth critical dimensions are extended in a second direction.

9. The semiconductor device of claim 1, wherein the metal contact is in contact with the first dielectric bar.

10. The semiconductor device of claim 1, further comprising a backside interlayer dielectric (BILD) located under a shallow trench isolation (STI), wherein the BILD includes materials different than the STI, a self-aligned substrate isolation layer, and a gate isolation layer.

11. The semiconductor device of claim 10, wherein the gate isolation layer includes nitride.

12. The semiconductor device of claim 10, wherein the BILD includes SiC or SiOC.

13. A method for forming a semiconductor device, the method comprising:
forming one or more source and drain regions above a substrate layer, each of the one or more source and drain regions having a filleted shape, wherein a bottom portion of the filleted shape includes a horizontal bottom surface connecting two sloped surfaces;
forming a first dielectric bar between each of the one or more source and drain regions; and
forming a metal contact surrounding two sloped surfaces on a backside of the semiconductor device.

14. The method of claim 13, further comprising:
forming a plurality of nanosheet gates extended between the one or more source and drain regions; and
forming a second dielectric bar between each two nanosheet gates of the plurality of nanosheet gates.

15. The method of claim 13, further comprising forming an airgap between two sloped surfaces on a frontside of the semiconductor device.

16. The method of claim 15, wherein forming the airgap further comprises sealing the airgap with the first dielectric bar, a shallow trench isolation layer and a gate.

17. The method of claim 13, further comprising forming a placeholder located under at least one of the one or more source and drain regions, wherein:
the placeholder is in contact with the horizontal bottom surface; and
the placeholder is not in contact with two sloped surfaces on a frontside of the semiconductor device.

18. The method of claim 17, wherein:
a first critical dimension of the metal contact is larger than a second critical dimension of the placeholder;
the first and second critical dimensions are extended in a first direction;
a third critical dimension of the metal contact is substantially equal to a fourth critical dimension of the placeholder; and
the third and fourth critical dimensions are extended in a second direction.

19. The method of claim 13, further comprising forming a backside interlayer dielectric (BILD) located under a shallow trench isolation (STI), wherein the BILD includes materials different than the STI, a self-aligned substrate isolation layer, and a gate isolation layer.

20. A semiconductor device, comprising:
one or more source and drain regions above a substrate layer, each of the one or more source and drain regions having a filleted shape, wherein a bottom portion of the filleted shape includes a horizontal bottom surface connecting two sloped surfaces;
an airgap between two sloped surfaces on a frontside of the semiconductor device; and
a first dielectric bar between each of the one or more source and drain regions.
